(19) United States
(12) Patent Application Publication
(10) Pub. No.: US 2025/0264548 A1
(43) Pub. Date: Aug. 21, 2025

(54) SYSTEM AND METHOD FOR MATCHED-PORT POWER SUPPLY EVALUATION

(71) Applicant: Machines to Help People, Inc., Edmond, OK (US)

(72) Inventors: James D. Nelson, Verona, MO (US); Wesley G. Colbert, Edmond, OK (US)

(21) Appl. No.: 19/044,133

(22) Filed: Feb. 3, 2025

Related U.S. Application Data
(60) Provisional application No. 63/554,626, filed on Feb. 16, 2024.

(51) Int. Cl. G01R 31/40

(52) U.S. Cl. CPC G01R 31/40

(57) ABSTRACT

An evaluation system and method are herein disclosed. The system comprises a housing; a first connector having a first positive contact, a first negative contact, and a first signal contact; a second connector having a second positive contact, a second negative contact, and a second signal contact; and an evaluation circuit. The evaluation circuit comprises a signal wire coupling the first signal contact and the second signal contact; a negative wire coupling the first negative contact and the second negative contact; a positive wire coupling the first positive contact and the second positive contact; and a multimeter having a sampling component associated with the positive wire, the multimeter being coupled to the positive wire and the negative wire and operable to determine a simultaneous current and a voltage based on a signal from the sampling component.

### CROSS-REFERENCE TO RELATED APPLICATIONS

The present patent application is a non-provisional application which claims priority to U.S. Provisional Application No. 63/554,626 titled “SYSTEM AND METHOD FOR MATCHED-PORT POWER SUPPLY EVALUATION”, filed on Feb. 16, 2024, the entire content of which is hereby expressly incorporated herein by reference in its entirety.

### BACKGROUND

In the realm of electronics testing and repair, a technician may often desire to test a power supply used for an electronic device. However, power supply operation varies in both physical connectivity and power supply activation. These variations make it difficult for technicians to test and verify that a power supply is supplying an appropriate voltage and current to the electronic device.

Over the years, it has been desirable to produce power supplies that are more efficient by not producing power unless or until the electronic device is connected, or requires the power. For example, certain power supplies may not produce power unless a particular pin of the power supply is activated, a circuit is completed, or a resistance is detected. Such power supplies, therefore, do not produce power unless connected to a specific type of electronic device, thereby making testing more difficult for the technician as the technician cannot simply test the power supply without the electronic device being present. However, with the electronic device present, the technician may not be able to test the power supply due to construction of the power supply and/or the electronic device.

Therefore, a need exists for an improved power supply evaluation system that addresses these limitations.

### SUMMARY

The problem of a technician being able to evaluate a power supply without use of the associated electronic device is solved by the systems and methods herein disclosed. The systems and methods generally include a system comprising a housing, a first connector, a second connector, and an evaluation circuit. The housing has a first side, a second side, and a peripheral wall extending from the first side to the second side. The first connector is supported by the housing and has a first positive contact, a first negative contact, and a first signal contact. The second connector is supported by the housing and has a second positive contact, a second negative contact, and a second signal contact. The evaluation circuit comprises a signal wire electrically coupling the first signal contact and the second signal contact; a negative wire electrically coupling the first negative contact and the second negative contact; a positive wire electrically coupling the first positive contact and the second positive contact; and a multimeter having a sampling component and being electrically coupled to the positive wire and the negative wire, the sampling component being associated with the positive wire, the multimeter further operable to determine at least one of a supply current and a supply voltage based on a signal from the sampling component.

The details of one or more implementations of the subject matter of this specification are set forth in the accompanying drawings and the description below. Other aspects, features and advantages will become apparent from the description, the drawings, and the claims.

### BRIEF DESCRIPTION OF DRAWINGS

The accompanying drawings, which are incorporated in and constitute a part of this specification, illustrate one or more implementations described herein and, together with the description, explain these implementations. The drawings are not intended to be drawn to scale, and certain features and certain views of the figures may be shown exaggerated, to scale or in schematic in the interest of clarity and conciseness. Not every component may be labeled in every drawing. Like reference numerals in the figures may represent and refer to the same or similar element or function. In the drawings:

FIG. 1 is a top view of an exemplary embodiment of an evaluation system constructed in accordance with the present disclosure.

FIG. 2 is a circuit diagram of an exemplary embodiment of an evaluation circuit constructed in accordance with the present disclosure.

FIG. 3 is a right-side perspective view of an exemplary embodiment of the evaluation system constructed in accordance with the present disclosure.

FIG. 4 is a left-side perspective view of an exemplary embodiment of the evaluation system constructed in accordance with the present disclosure.

FIG. 5 is a bottom view of an exemplary embodiment of the evaluation system constructed in accordance with the present disclosure.

FIGS. 6-7 are diagrams of exemplary embodiments of a device supply cable and a device load cable, respectively, constructed in accordance with the present disclosure.

### DETAILED DESCRIPTION

Before explaining at least one embodiment of the disclosure in detail, it is to be understood that the disclosure is not limited in its application to the details of construction, experiments, exemplary data, and/or the arrangement of the components set forth in the following description or illustrated in the drawings unless otherwise noted. The disclosure is capable of other embodiments or of being practiced or carried out in various ways. Also, it is to be understood that the phraseology and terminology employed herein is for purposes of description and should not be regarded as limiting.

As used in the description herein, the terms “comprises,” “comprising,” “includes,” “including,” “has,” “having,” or any other variations thereof, are intended to cover a non-exclusive inclusion. For example, unless otherwise noted, a process, method, article, or apparatus that comprises a list of elements is not necessarily limited to only those elements but may also include other elements not expressly listed or inherent to such process, method, article, or apparatus.

Further, unless expressly stated to the contrary, “or” refers to an inclusive and not to an exclusive “or”. For example, a condition A or B is satisfied by one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the inventive concept. This description should be read to include one or more, and the singular also includes the plural unless it is obvious that it is meant otherwise. Further, use of the term “plurality” is meant to convey “more than one” unless expressly stated to the contrary.

As used herein, qualifiers like “substantially,” “about,” “approximately,” and combinations and variations thereof, are intended to include not only the exact amount or value that they qualify, but also some slight deviations therefrom, which may be due to computing tolerances, computing error, manufacturing tolerances, measurement error, wear and tear, stresses exerted on various parts, and combinations thereof, for example.

As used herein, any reference to “one embodiment,” “an embodiment,” “some embodiments,” “one example,” “for example,” or “an example” means that a particular element, feature, structure, or characteristic described in connection with the embodiment is included in at least one embodiment and may be used in conjunction with other embodiments. The appearance of the phrase “in some embodiments” or “one example” in various places in the specification is not necessarily all referring to the same embodiment, for example.

The use of ordinal number terminology (i.e., “first”, “second”, “third”, “fourth”, etc.) is solely for the purpose of differentiating between two or more items and, unless explicitly stated otherwise, is not meant to imply any sequence or order of importance to one item over another.

The use of the term “at least one” or “one or more” will be understood to include one as well as any quantity more than one. In addition, the use of the phrase “at least one of X, Y, and Z” will be understood to include X alone, Y alone, and Z alone, as well as any combination of X, Y, and Z.

Circuitry, as used herein, may be analog and/or digital components, or one or more suitably programmed processors (e.g., microprocessors) and associated hardware and software, or hardwired logic. Also, “components” may perform one or more functions. The term “processing component,” may include hardware, such as a processor (e.g., microprocessor), an application specific integrated circuit (ASIC), a field programmable gate array (FPGA), a combination of hardware and software, software, and/or the like. The term “processor” as used herein means a single processor or multiple processors working independently or together to collectively perform a task.

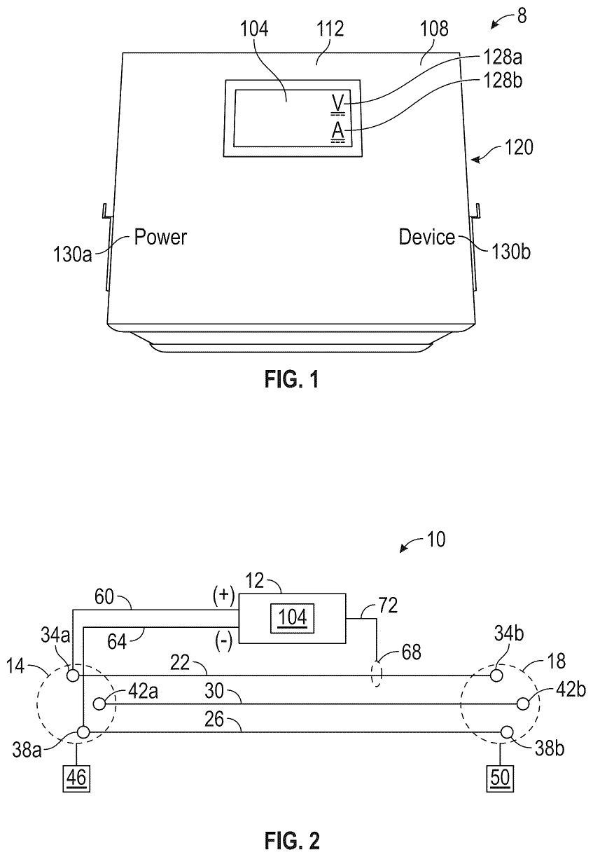

Referring now to the drawings, and in particular to FIG. 1, shown therein is an evaluation system 8 constructed in accordance with the present disclosure. As will be described below, the evaluation system 8 includes at least one evaluation circuit 10 shown in FIG. 2. The evaluation circuit 10 is configured to evaluate whether or not a particular power supply made to operate with a particular electrical device is working properly. The details of the evaluation circuit 10 will be described below.

In general, and shown in FIG. 2, the evaluation circuit 10 comprises a multimeter 12 disposed between a first connector 14 and a second connector 18, which are electrically coupled via at least three conductive wires, including a positive wire 22, a negative wire 26, and a signal wire 30. Each connector (e.g., the first connector 14 and the second connector 18) may comprise a plurality of electrical contacts, such as a positive contact 34, a negative contact 38, and a signal contact 42. In one implementation, the multimeter 12 may be constructed similar to exemplary high-current voltmeter WLS-TVA050 (unknown manufacturer). It should be understood that a “negative” wire or other component may also be referred to as a “ground” wire or component or as a “common” wire or component.

For example, as shown in FIG. 1, the first connector 14 has a first positive contact 34a electrically coupled to a second positive contact 34b of the second connector 18 via the positive wire 22, a first negative contact 38a electrically coupled to a second negative contact 38b of the second connector 18 via the negative wire 26, and a first signal contact 42a electrically coupled to a second signal contact 42b via the signal wire 30.

In one implementation, each wire (e.g., the positive wire 22, the negative wire 26, and the signal wire 30) may be implemented as a conductor operable to carry an electric current. The conductor may be, for example, an isolated conductor surrounded by a flexible, non-conducting shield that may be stripped off of the conductor when the conductor is electrically coupled to a respective contact. In some implementations, each wire is a particular trace on a circuit board. In one embodiment, each wire may be either a solid core wire or a stranded wire. In one embodiment, each wire may have a gauge of between 22 and 10 AWG. In one implementation, each wire may have a gauge selected to safely carry a maximum current of a device supply 46 (discussed below).

In some implementations, each of the negative wire 26 and the signal wire 30 are independent and not a part of another circuit disposed between the first and second conductors. In some implementations, at least one of the negative wire 26 and the signal wire 30 is only electrically coupled to respective negative contacts or signal contacts.

In one implementation, the first connector 14 may be configured to be coupled to a device supply 46. The device supply 46 may be coupled to the first connector 14 by a technician, for example. A positive supply of the device supply 46 may be electrically coupled to the first positive contact 34a, a negative supply of the device supply 46 may be electrically coupled to the first negative contact 38a, and a signal supply (if present) of the device supply 46 may be electrically coupled to the first signal contact 42a. The second connector 18 may be configured to be coupled to a device load 50. The device load 50 may be coupled to the second connector 18 by the technician, for example. A positive load of the device load 50 may be electrically coupled to the second positive contact 34b, a negative load of the device load 50 may be electrically coupled to the second negative contact 38b, and a signal load (if present) of the device load 50 may be electrically coupled to the second signal contact 42b. In this way, the evaluation circuit 10 is electrically disposed between the device supply 46 and the device load 50 so that the device load 50 can electrically interact with the device supply 46 to establish a supply of power from the device supply 46 to the device load 50. In some embodiments, the evaluation circuit 10 is configured to mimic electrical properties (e.g., resistance, capacitance, inductance) of an extension cord having a length in a range from one inch to one foot, and a gauge in a range from 24 gauge to 8 gauge depending upon the voltage and current capacity that the device supply 46 is designed to provide to the device load 50.

In one implementation, the device load 50 is a jumper component operable to matingly engage with the second connector 18. The jumper component may bridge one of the second positive contact 34b and the second negative contact 38b with the second signal contact 42b. In this way, for example, to test an ATX power supply, the ATX power supply may be coupled to a device supply adapter 150 (shown in FIG. 6 and discussed in more detail below), and the jumper component may be connected to the second connector 18 to connect the second signal contact 42b to the second negative contact 38b thereby causing the PS_ON # pin of the ATX power supply to be electrically connected to the common ground/negative supply line of the ATX power supply.

In one implementation, the multimeter 12, being coupled to the positive wire 22 and the negative wire 26 may receive a voltage and current operable to power the multimeter 12 during operation of the evaluation circuit 10. Upon powering on, the multimeter 12 may determine at least one of: a supply voltage and a supply current. In one implementation, the multimeter 12 may be operable to measure the supply current and a supply voltage simultaneously. In one implementation, the multimeter 12 may be operable to measure the supply current and a supply voltage simultaneously and without the technician placing a probe in direct contact with the device supply 46.

In one implementation, the first connector 14 and the second connector 18 are a same connector type. For example, both the first connector 14 and the second connector 18 may be constructed identically to one another. For example, both the first connector 14 and the second connector 18 may be either a plug type or a socket type.

In one implementation, the first connector 14 and the second connector 18 are constructed to be complementary to each other. For example, the first connector 14 may be one of a plug type and a socket type and the second connector 18 may be the other one of the plug type or the socket type.

In one implementation, the evaluation circuit 10 further comprises a positive supply 60 electrically coupling the first positive contact 34a of the first connector 14 to the multimeter 12 and a negative supply 64 electrically coupling the first negative contact 38a of the first connector 14 to the multimeter 12. In other embodiments, the positive supply 60 may be electrically coupled to the second positive contact 34b of the second connector 18 and the negative supply 64 electrically coupled to the second negative contact 38b of the second connector 18 to the multimeter 12. Because the first connector 14 is coupled to the second connector 18 in a manner to simulate electrical properties, e.g., of an extension cord, the positive supply 60 may be electrically coupled to the first positive contact 34a, the second positive contact 34b or the positive wire 22; and the negative supply 64 may be electrically coupled to the first negative contact 38a, the second negative contact 38b, or the negative wire 26.

In one implementation, the multimeter 12 may be electrically coupled to a sampling component 68 via a sampling wire 72. The sampling component 68 may be an electronic device operable to detect and/or measure an electric field. For example, the sampling component 68 may be a Hall-effect sensor operable to transduce magnetic fields into electrical signals. In one implementation, the Hall-effect sensor may be operable to produce a voltage proportional to at least one axial component of the magnetic field. As shown in FIG. 1, the sampling component 68 may be constructed so as to encircle the positive wire 22, thereby enabling the sampling component 68 to measure a magnetic field surrounding the positive wire 22 and to create a signal indicative of the measurement, such as by creating a voltage signal dependent on a strength of at least one axial component of the magnetic field. The signal may be carried by the sampling wire 72 thereby providing the measurement to the multimeter 12.

In one implementation, the multimeter 12 may determine at least one of the supply voltage and the supply current, as supplied by the device supply 46. The supply voltage may be determined, for example, by measuring a voltage between the positive wire 22 and the negative wire 26, thereby measuring the voltage between the first positive contact 34a in electrical communication with the positive supply of the device supply 46 and the first negative contact 38a in electrical communication with the negative supply of the device supply 46. The supply current may be determined, for example, by measuring a current passing through the positive wire 22, such as by receiving the measurement from the sampling component 68 via the sampling wire 72.

In one implementation, the multimeter 12 may further include one or more output device 104 (shown below in FIG. 2). The one or more output device 104 may be capable of outputting information in a form perceivable by the technician. The one or more output device 104 may be one or more of: a monitor, a screen (e.g., an LED screen, an LCD screen, an OLED screen, one or more segmented display, and/or a dot matrix display), a touchscreen, a speaker, a television, combinations thereof, and the like, for example. The one or more output device 104 may be a screen (e.g., LED screen, LCD screen or the like) operable to display at least one or more of the supply voltage and the supply current. In one implementation, the one or more output device 104 may display only one of the supply voltage and the supply current at a first instance in time and the other of the supply voltage and the supply current at a second instance in time. In one implementation, the one or more output device 104 may display only one of the supply voltage and the supply current that the multimeter 12 is able to detect and/or measure. In one implementation, the supply current is a direct current; however, in other implementations, the supply current may alternatively be an alternating current. In some implementations, the evaluation circuit 100 may only be able to detect the supply current when the supply current is DC (a direct current), and may not be able to detect the supply current when the supply current is AC.

In one implementation, two or more of the components of the evaluation circuit 10 may be integrated into a circuit board or two or more components of the evaluation circuit 10 may be integrated into each other. For example, each of the wires (e.g., the positive wire 22, the negative wire 26, and the signal wire 30) may be integrated into the circuit board as respective traces. Additionally, the number of devices illustrated in FIG. 2 is provided for explanatory purposes. In practice, there may be additional devices, fewer devices, different devices, or differently arranged devices than are shown in FIG. 2. For example, the evaluation circuit 10 may include components such as LED indicators (e.g., as the one or more one or more output device 104 capable of outputting information).

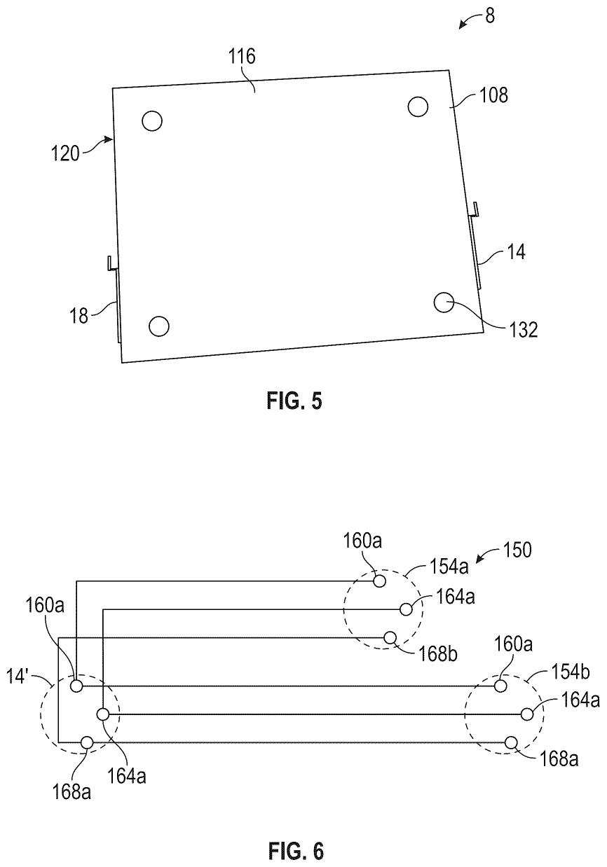

Referring back to FIG. 1, shown therein is a top view of an exemplary embodiment of an evaluation system 8 constructed in accordance with the present disclosure. The housing 108 may generally comprise a first side 112, an opposed second side 116 (shown in FIG. 5), and a perimeter wall 120 extending from the first side 112 to the second side 116.

In one implementation, the housing 108 supports the evaluation circuit 10 (FIG. 2), the first connector 14, the second connector 18, and the one or more output device 104. For example, as shown, the one or more output device 104 may be supported by the first side 112. The first connector 14 and the second connector 18 may be connected to the housing 108 and supported by the perimeter wall 120 of the housing 108, for example, at different locations of the housing 108. The one or more output device 104 may further include one or more power label 128 such as a first power label 128a, shown in FIG. 1 as “V”, indicative of the supply voltage and a second power label 128b, shown in FIG. 1 as “A”, indicative of the supply current.

In one implementation, the one or more power label 128 may be printed onto the one or more output device 104, may be an adhesive label affixed to the one or more output device 104, may be a placard affixed to the one or more output device 104, and/or may be otherwise attached to, or associated with, the one or more output device 104.

In one implementation, the housing 108 may further include one or more device label 130 disposed on the first side 112 and indicative of whether the device supply 46 or the device load 50 is to be electrically coupled to the first connector 14 and the second connector 18. The one or more device label 130 is shown in FIG. 1 as a first device label 130a and a second device label 130b. Each device label 130 may be positioned nearer one of the first connector 14 and the second connector 18 than the other of the first connector 14 and the second connector 18.

In one implementation, the one or more device label 130 may be one or more of: a logo, a word, a phrase, an icon, a photographic representation, and/or the like. In one embodiment, the one or more device label 130 may be embossed, that is, the one or more device label 130 may be formed into the first side 112 and extend from the first side 112 away from the housing 108 or may extend from the first side 112 into the housing 108 towards the second side 116.

In one implementation, the one or more device label 130 and/or the one or more power label 128 may be printed onto the first side 112, may be an adhesive label affixed to the first side 112, may be a placard affixed to the first side 112, and/or may be otherwise attached to, or associated with, the first side 112.

In one implementation, the evaluation system 8 may comprise more than one evaluation circuit 10. For example, the evaluation system 8 may comprise a first evaluation circuit 10 and a second evaluation circuit 10, where the first evaluation circuit 10 and the second evaluation circuit 10 are identically constructed with the exception that the first connector 14 and second connector 18 of the first evaluation circuit 10 has a first connector kind while the first connector 14 and the second connector 18 of the second evaluation circuit 10 has a second connector kind different from the first connector kind. In one implementation, the first evaluation circuit 10 may have a first multimeter 12 with a first output device 104 and the second evaluation circuit 10 may have a second multimeter 12 different from the first multimeter 12 with a second output device 104 different from the first output device 104. Alternatively, the first evaluation circuit 10 and the second evaluation circuit 10 may share a same multimeter 12 and a same output device 104. In other implementations, the first evaluation circuit 10 and the second evaluation circuit 10 share one of: the multimeter 12 and the one or more output device 104.

The number of devices illustrated in FIG. 1 is provided for explanatory purposes. In practice, there may be additional devices, fewer devices, different devices, or differently arranged devices than are shown in FIG. 1.

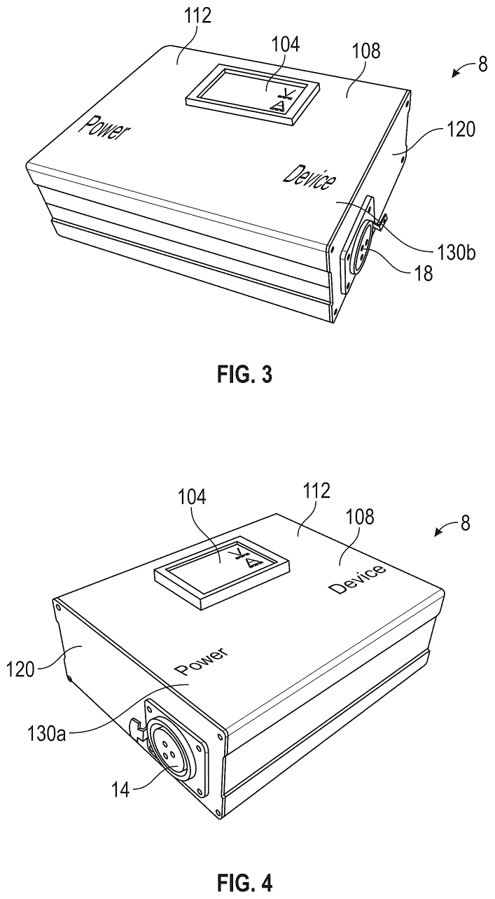

Referring now to FIG. 3, shown therein is a right-side perspective view of an exemplary embodiment of the evaluation system 8, constructed in accordance with the present disclosure. As shown, the perimeter wall 120 of the housing 108, extending from the first side 112 to the second side 116, may support the first connector 14 (shown in FIG. 4) and the second connector 18. As shown, the second device label 130b may be positioned near the second connector 18 and have a text of “Device”, indicating that the second connector 18 is associated with and configured to be electrically coupled to the device load 50.

In one implementation, as shown in FIG. 3, the second connector 18 is a locking XLR3 jack. However, the second connector 18 may be constructed of a different jack type having at least three contacts, e.g., for the positive contact 34, the negative contact 38 and the signal contact 42.

Referring now to FIG. 4, shown therein is a left-side perspective view of an exemplary embodiment of the evaluation system 8 constructed in accordance with the present disclosure. As shown, the perimeter wall 120 of the housing 108, extending from the first side 112 to the second side 116, may support the first connector 14. As shown, the first device label 130a may be positioned near the first connector 14 and have a text of “Power”, indicating that the first connector 14 is associated with and configured to be electrically coupled to the device supply 46.

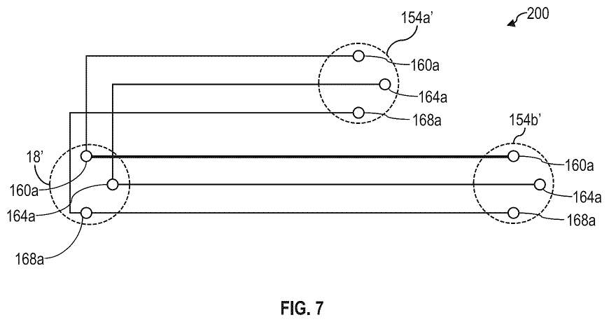

In one implementation, as shown in FIG. 4, the first connector 14 is constructed in accordance with, and has a same type as, the second connector 18, i.e., the first connector 14 is a locking XLR3 jack. However, the first connector 14 may be constructed of a different jack type having at least three contacts, e.g., for the positive contact 34, the negative contact 38 and the signal contact 42. The first connector 14 and the second connector 18 may have a same jack type. The first connector 14 is configured to have an opposite jack type as (e.g., a jack type operable to matingly engage with) a complementary first connector 14′ (see FIG. 6), and the second connector 18 is configured to have an opposite jack type as (e.g., a jack type operable to matingly engage with) a complementary second connector 18′ (see FIG. 7). In this way, the complementary first connector 14′ may be mechanically coupled to the first connector 14, and the complementary second connector 18′ may be mechanically coupled to the second connector 18.

Referring now to FIG. 5, shown therein is a bottom view of an exemplary embodiment of the evaluation system 8 constructed in accordance with the present disclosure. As shown in FIG. 5, the second side 116 of the housing 108 may provide support for the perimeter wall 120.

In one implementation, the second side 116 may further (optionally) comprise one or more support pads 132. The support pads 132 may be constructed of a non-conductive material such that the evaluation system 8 is electrically isolated from a surface on which it is placed. Additionally, the support pads 132 may increase friction between the evaluation system 8 and the surface, thereby reducing movement or slippage of the evaluation system 8 during use, such as, when the technician electrically couples the complementary first connector 14′ coupled to the device supply 46 and/or the complementary second connector 18′ electrically coupled to the device load 50, with the evaluation system 8.

Referring now to FIGS. 6 and 7, shown therein are diagrams of exemplary embodiments of a device supply adapter 150 and a device load adapter 200 constructed in accordance with the present disclosure. Generally, the device supply adapter 150 and the device load adapter 200 may be constructed such that a particular device supply adapter 150 may be operable to receive a connection from power supplies 45 having different connector types and a particular device load adapter 200 may be operable to receive a connection from device loads 50 having different connector types.

In one implementation, the technician may use a particular pair of the device supply adapter 150 and the device load adapter 200 that have connectors matched to a particular power supply/device load pair. For example, the technician may connect a particular power supply to a particular device supply adapter 150 and connect the particular device supply adapter 150 to the first connector 14 of the evaluation system 8 and may connect a particular device load to a particular device load adapter 200 and connect the particular device load adapter 200 to the second connector 18 of the evaluation system 8. The Technician may then receive the output of the one or more output device 104 as an indication of the supply voltage and the supply current/amperage to assess the device supply 46 and/or the device load 50.

Each of the device supply adapter 150 and the device load adapter 200 may function to connect the device supply 46 to the first connector 14 and the device load 50 to the second connector 18 of the evaluation system 8 without substantially interfering with the supply current or the supply voltage of the device supply 46 such that the technician can monitor and/or assess functionality of the device supply 46 and device load 50 pair.

In one implementation, the device supply adapter 150 may have the complementary first connector 14′ operable to be mechanically coupled to the first connector 14. The complementary first connector 14′ of the device supply adapter 150 may be electrically coupled to one or more device connector 154, shown in FIG. 6 as a first device connector 154a and a second device connector 154b. For example, a first contact 160a of the complementary first connector 14′ may be electrically coupled to a first contact 160a of the first device connector 154a and a first contact 160a of the second device connector 154b, a second contact 164a of the complementary first connector 14′ may be electrically coupled to a second contact 164a of the first device connector 154a and a second contact 164a of the second device connector 154b, and a third contact 168a of the complementary first connector 14′ may be electrically coupled to a third contact 168a of the first device connector 154a and a third contact 168a of the second device connector 154b. In this way, when the complementary first connector 14′ is mechanically coupled to the first connector 14, e.g., by the technician, the first contact 160a is in electrical contact with the first positive contact 34a, the second contact 164a is in electrical contact with the first signal contact 42a, and the third contact 168a is in electrical contact with the first negative contact 38a.

In one implementation, the device load adapter 200 may have the complementary second connector 18′ operable to be mechanically coupled to the second connector 18. The complementary second connector 18′ of the device load adapter 200 may be electrically coupled to one or more complementary device connectors 154′, shown in FIG. 7 as a complementary first device connector 154a′ and a complementary second device connector 154b′. For example, a first contact 160a of the complementary second connector 18′ may be electrically coupled to a first contact 160a of the complementary first device connector 154a′ and a first contact 160a of the complementary second device connector 154b′, a second contact 164a of the complementary second connector 18′ may be electrically coupled to a second contact 164a of the complementary first device connector 154a′ and a second contact 164a of the complementary second device connector 154b′, and a third contact 168a of the complementary second connector 18′ may be electrically coupled to a third contact 168a of the complementary first device connector 154a′ and a third contact 168a of the complementary second device connector 154b′. In this way, when the complementary second connector 18′ is mechanically coupled to the second connector 18, e.g., by the technician, the first contact 160a is in electrical contact with the second positive contact 34b, the second contact 164a is in electrical contact with the second signal contact 42b, and the third contact 168a is in electrical contact with the second negative contact 38b.

Each of the one or more device connector 154 may have a different connector kind. In other words, the first device connector 154a may have a first connector kind, while the second device connector 154b may have a second connector kind. Each connector kind may be, for example, a particular kind of connector, such as a JST connector, a barrel connector, a Molex connector, an IDC connector, a DIN connector, a USB connector, an XLR connector, an ATX (24 or 20+4 pin) power supply unit connector, an ATX12V connector, an EPS 8-pin connector, a PCIe 6-pin connector, a IEC 320 C13/C14 connector, an IEC 320 C5 connector, an IEC 320 C7 (polarized or non-polarized), a USB connector (Type-A or Type-C, for example), and/or the like. In one implementation, when the connector kind has more than three contacts, the technician may select three of the more than three contacts to electrically couple to the evaluation circuit 10, e.g., to the first positive contact, the first negative contact, and the first signal contact of the first connector 14, for example.

In some embodiments, when the device supply 46 and the device load 50 have a connector kind that does not include a signal contact (and/or another contact other than a positive contact and a negative contact), the device supply adapter 150 and the device load adapter 200 may not include a conductor coupled to the second contact 164a, for example, or the second contact 164a may be omitted from the device supply adapter 150 and/or the device load adapter 200.

Each of the one or more device connector 154 may have a same connector type, that is, each of the one or more device connector 154 may be one of: a plug type and a socket type, however, in other implementations, not all of the one or more device connectors 154 have the same connector type. Each of the one or more complementary device connector 154′ may have a connector complementary to at least one of the one or more device connector. For example, the first device connector 154a may have a first connector kind and a first connector type and the complementary first device connector 154a′ may have the first connector kind and a second connector type complementary to the first connector type, e.g., operable to be mechanically, and electrically, coupled to the first connector type.

In one implementation, the technician, being presented with a user device having a device supply and a device load with a first connector kind may select a device supply adapter 150, having a first connector type similar to the device load, and may connect the device supply to the first device connector 154a and connect the complementary first connector 14′ of the device supply adapter 150 to the first connector 14 of the evaluation device 8. The technician may then select a device load adapter 200, having a second connector type complementary to the first connector type and similar to the device supply, and may connect the device load to the complementary first device connector 154a′ and connect the complementary second connector 18′ of the device load adapter 200 to the second connector 18 of the evaluation device 8.

In this way, the device supply, having the first connector type, is coupled to the device supply adapter 150, which is operable to be coupled to the first connector 14 of the evaluation system 8 and the device load, having the second connector type, is coupled to the device load adapter 200, which is operable to be coupled to the second connector 18 of the evaluation system 8. Thus, the evaluation circuit 10 of the evaluation system 8 may be electrically disposed between the device supply and the device load.

From the above description, it is clear that the inventive concept(s) disclosed herein are well adapted to carry out the objects and to attain the advantages mentioned herein, as well as those inherent in the inventive concept(s) disclosed herein. While the embodiments of the inventive concept(s) disclosed herein have been described for purposes of this disclosure, it will be understood that numerous changes may be made and readily suggested to those skilled in the art which are accomplished within the scope and spirit of the inventive concept(s) disclosed herein.

What is claimed is:

1. A system, comprising:
a housing having a first side, a second side, and a perimeter wall extending from the first side to the second side;
a first connector supported by the housing and having a first positive contact, a first negative contact, and a first signal contact;
a second connector supported by the housing and having a second positive contact, a second negative contact, and a second signal contact; and
an evaluation circuit, comprising:
a signal wire electrically coupling the first signal contact and the second signal contact;
a negative wire electrically coupling the first negative contact and the second negative contact;
a positive wire electrically coupling the first positive contact and the second positive contact; and
a multimeter having a sampling component and being electrically coupled to the positive wire and the negative wire, the sampling component being associated with the positive wire, the multimeter further operable to determine at least one of: a supply voltage and a supply current based on a signal from the sampling component.

2. The system of claim 1, wherein the sampling component is operable to measure an electromagnetic field of the positive wire.

3. The system of claim 2, wherein the sampling component is a Hall-effect sensor.

4. The system of claim 1, wherein the signal is a voltage signal indicative of a strength of at least one axial component of a magnetic field inducted by a supply current flowing in the positive wire.

5. The system of claim 1, wherein at least one of the first connector and the second connector are supported by the perimeter wall.

6. The system of claim 1, wherein the first connector is supported at a first location on the perimeter wall and the second connector is supported at a second location on the perimeter wall different from the first location.

7. The system of claim 1, wherein the multimeter further includes one or more output device operable to receive and output an indication of at least one of: the supply voltage and the supply current.

8. The system of claim 7, wherein the one or more output device is operable to output the indication of both the supply voltage and the supply current simultaneously.

9. The system of claim 8, wherein the one or more output device is operable to output the indication of both the supply voltage and the supply current simultaneously without a technician placing a probe in direct contact with a device supply.

10. The system of claim 1, wherein the first connector and the second connector have a same connector type.

11. The system of claim 10, wherein the same connector type is a first connector type, and further comprising:
a device supply adapter having a complementary first connector and a first device connector having a second connector type, the complementary first connector having a third connector type complementary to the first connector type; and
a device load adapter having a complementary second connector and a complementary first device connector having a fourth connector type complementary to the second connector type, the complementary second connector having the third connector type complementary to the first connector type.

12. The system of claim 11, wherein the device supply adapter further comprises a second device connector having a fifth connector type; and the device load adapter further comprises a complementary second device connector having a sixth connector type complementary to the fifth connector type.

13. The system of claim 1, further comprising:
a jumper component configured to be mechanically coupled to at least one of the first connector and the second connector; and
wherein the jumper component is operable to electrically couple at least one of: a respective negative contact and a respective positive contact, with a respective signal contact.

14. The system of claim 1, wherein the evaluation circuit is configured to mimic at least one of: a resistance, capacitance, and inductance, of an extension cord having a length of between about 1 inch and 1 foot.

15. The system of claim 1, wherein the negative wire is only electrically coupled to the first negative contact and the second negative contact.

16. The system of claim 1, wherein the signal wire is only electrically coupled to the first signal contact and the second signal contact.

17. An evaluation system, comprising:
a housing having a first side, a second side, and a perimeter wall extending from the first side to the second side;
a first evaluation circuit, comprising:
a first connector supported by the housing and having a first connector type, the first connector comprising a first positive contact, a first negative contact, and a first signal contact;
a second connector supported by the housing and having a second connector type, the second connector comprising a second positive contact, a second negative contact, and a second signal contact;
a first signal wire electrically coupling the first signal contact and the second signal contact;
a first negative wire electrically coupling the first negative contact and the second negative contact; and
a first positive wire electrically coupling the first positive contact and the second positive contact;
a second evaluation circuit, comprising:
a third connector supported by the housing and having a third connector type, the third connector comprising a third positive contact, a third negative contact, and a third signal contact;
a fourth connector supported by the housing and having a fourth connector type, the fourth connector comprising a fourth positive contact, a fourth negative contact, and a fourth signal contact;
a second signal wire electrically coupling the third signal contact and the fourth signal contact;
a second negative wire electrically coupling the third negative contact and the fourth negative contact; and
a second positive wire electrically coupling the third positive contact and the fourth positive contact; and
a multimeter being electrically coupled between the first positive wire and the first negative wire, and between the second positive wire and the second negative wire, the multimeter further comprising a first sampling component being associated with the first positive wire and a second sampling component being associated with the second positive wire, the multimeter further operable to determine at least one of: a first supply voltage of the first evaluation circuit, a first supply current of the first evaluation circuit, a second supply voltage of the second evaluation circuit, and a second supply current of the second evaluation circuit, based on a signal from the first sampling component and the second sampling component, respectively.

18. The evaluation system of claim 17, further comprising an output device operable to receive and output an indication of at least one of: the first supply voltage, the first supply current, the second supply voltage, and the second supply current.

19. The evaluation system of claim 18, wherein the output device is operable to output the indication of at least one of: the first supply voltage and the first supply current or of the second supply voltage and the second supply current, simultaneously.

20. The evaluation system of claim 17, wherein the second connector type is the same as the first connector type and the fourth connector type is the same as the third connector type, and wherein the third connector type is different from the first connector type.
